(19) United States
(12) Patent Application Publication
(10) Pub. No.: US 2024/0319301 A1
(43) Pub. Date: Sep. 26, 2024

(54) MAGNETIC RESONANCE APPARATUS WITH A FREE-RUNNING RECEIVE CHAIN AND METHOD FOR OPERATION

(71) Applicant: Siemens Healthineers AG, Forchheim (DE)

(72) Inventors: Stephan Biber, Erlangen (DE); Nikolaus Demharter, Dormitz (DE)

(21) Appl. No.: 18/611,127

(22) Filed: Mar. 20, 2024

(30) Foreign Application Priority Data
Mar. 20, 2023 (DE) 10 2023 202 435.7

(51) Int. Cl. G01R 33/36; G01R 33/54; G01R 33/58

(52) U.S. Cl. CPC G01R 33/3621; G01R 33/543; G01R 33/583

(57) ABSTRACT

A magnetic resonance apparatus and a method for operation of the magnetic resonance apparatus are provided. The magnetic resonance apparatus includes a local coil for acceptance and transmission of magnetic resonance signals to the magnetic resonance apparatus. A delay of the magnetic resonance signal between receipt by the local coil and arrival at the magnetic resonance apparatus is variable. In one act of the method, the magnetic resonance apparatus establishes a delay of the magnetic resonance signal between the local coil and the magnetic resonance apparatus and, in a further act, carries out a signal processing process of the transmitted magnetic resonance signal depending on the delay established.

This application claims the benefit of German Patent Application No. DE 10 2023 202 435.7, filed on Mar. 20, 2023, which is hereby incorporated by reference in its entirety.

### BACKGROUND

The present embodiments relate to a magnetic resonance apparatus with a free-running local coil, as well as a method for synchronization of the local coil.

Independent of the grammatical term usage, individuals with male, female, or other gender identities are included within the term.

Magnetic resonance apparatuses include magnetic resonance tomographs for imaging, but also other apparatuses that carry out measurements on examination objects by means of magnetic resonance.

Magnetic resonance apparatuses are apparatuses that detect properties of an examination object, in that magnetic resonance apparatuses align the nuclear spins of the examination object with a strong external magnetic field and excite the nuclear spins into precession about this alignment by a magnetic alternating field. The precession or return of the spins from this excited state into a state with lower energy generates a magnetic alternating field as a response, which is received via antennas.

The signals for imaging have spatial encoding impressed on the signals with the aid of magnetic gradient fields, which subsequently makes it possible to assign the signals received to a volume element. The received signal is then evaluated, and a three-dimensional representation of the examination object is provided. Local receive antennas, known as local coils, may be used for receiving the signal, which, to achieve an improved signal-to-noise ratio, are arranged directly on the examination object. The receive antennas may also be built into a patient couch.

Magnetic resonance measurements and, for example, imaging using magnetic resonance are sensitive to signal delays. The phase of the signals is used for spatial encoding, and the time reference to the excitation pulse is important for the signal detection. With an analog cabled connection between the antenna and the receiver, the time delays are deterministic for an individual local coil. When a local coil is changed, however, the delay may change. If the received signal is digitized, additional variable delays may occur.

A method for the creation and evaluation of analog time stamps is known from published patent U.S. Pat. No. 10,663,543 B2.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a time reference for received magnetic resonance signals is improved.

An embodiment of a magnetic resonance apparatus includes a local coil for accepting and transmitting magnetic resonance signals to the magnetic resonance apparatus. An antenna for receipt of magnetic resonance signals may be a local coil, with which a detachable connection to the magnetic resonance apparatus may be made in a signal connection for transmission of magnetic resonance signals and also control signals (e.g., also a wireless signal connection). A delay of the magnetic resonance signal between receipt by the local coil and entry into the magnetic resonance apparatus or a receiver of the magnetic resonance apparatus in this case is not deterministically preordained by the magnetic resonance apparatus (e.g., the delay may vary). This may be caused, for example, by the digital signal processing or transmission processes.

The magnetic resonance apparatus of the present embodiments is further configured to establish or to quantify the delay.

The magnetic resonance apparatus is configured to undertake a signal processing process of the magnetic resonance system transmitted depending on the delay established. For example, the magnetic resonance tomograph is configured to prevent or to compensate for disadvantageous effects of the variable delay in the signal processing. Different options for this are set out below.

In one embodiment, the magnetic resonance apparatus of the present embodiments, by detection of the delay and the signal processing depending on the detected value, makes possible a simplification of flexibilization of the system architecture, which may be used, for example, for a cost reduction or for an improvement in user convenience.

In one embodiment, the magnetic resonance apparatus may have a plurality of local coils. When a local coil is changed, the delay may change in such cases. The variable delay may relate both to the transmission of received magnetic resonance signals from the local coil to a receiver of the magnetic resonance signal and also to the exchange of control signals between the local coil and the magnetic resonance apparatus.

The magnetic resonance apparatus also includes a central clock. A clock generator from which the different clock signals in the magnetic resonance apparatus may be derived is referred to as a central clock, and the central clock specifies the time reference for the different activities of imaging. For example, the central clock also specifies the reference point for relative and absolute time specifications within the magnetic resonance apparatus. The local coil has a local clock that accordingly takes over the function of the central clock for the signal processing processes in the local coil.

The magnetic resonance apparatus is configured to synchronize the local clock with the central clock. This is to be understood as the local clock and the central clock, after the synchronization, having both a predetermined phase relationship and also a common absolute reference point for time determination. What may be achieved by the synchronization is that a phase position may be established for magnetic resonance signals received from the local coil (e.g., for magnetic resonance signals of a number of channels of a local coil or of a number of different local coils). Options for synchronization of the local clock and the central clock will be specified below.

Synchronous local clocks in the local coil and central clock (e.g., with wireless local coils) make it possible to make the system architecture simpler and more flexible, which may be utilized, for example, for a cost reduction or an improvement in user convenience.

The method of the present embodiments shares the advantage of the magnetic resonance apparatus of the present embodiments.

In one form of embodiment, the magnetic resonance apparatus is configured to establish the delay using a calibration measurement. A calibration measurement may be a measurement process in which a defined and reproducible time reference for a signal to be detected in the calibration measurement is present, and thus, the variable delay may be determined.

The calibration measurement makes it possible for the magnetic resonance apparatus to establish the variable delay once again, at least after every change (e.g., a replacement of a local coil), without taking account of external measurement devices in the signal processing.

In one possible form of embodiment of the magnetic resonance system, the local coil has an encoder for a time stamp in the magnetic resonance signal. This is to be understood as the magnetic resonance signal received from the local coil and forwarded to the magnetic resonance apparatus having information impressed on the magnetic resonance signal that specifies a point in time of the receipt of the magnetic resonance signal. The point in time may be defined, for example, in relation to a local clock of the local coil. In one form of embodiment, the local clock of the local coil may be synchronized with a central clock generator of the magnetic resonance tomograph. In one embodiment, however, the magnetic resonance tomograph may permanently transmit time information to the local coil as a function of the central clock generator, and the central clock generator may use the time information in order to generate the time stamp.

The encoder is configured in this case to impress the time stamp onto the magnetic resonance signal or to add the time stamp such that an imaging from the magnetic resonance signal will not be negatively influenced or only be influenced to a slight extent by the time stamp. With a digitized magnetic resonance signal, the time stamp may be inserted in time division multiplexing into the data stream or be part of a header of a data packet with the magnetic resonance signal. With an analog magnetic resonance signal, for example, techniques with spread spectrum below a noise level may be provided, or a transmission in a frequency band outside the bandwidth of the magnetic resonance signals may be detected for the imaging.

The magnetic resonance apparatus or a receiver of the magnetic resonance apparatus is configured to extract this time stamp from the magnetic resonance signal via a decoder and to make the time stamp available for further processing. In a complementary manner to the examples given above for the encoder, this may be done by a digital demultiplexer, a frequency filter with a downstream demodulator, or by a demodulator for the spread spectrum used.

The impression of a time stamp makes possible a permanent determination or detection of the variable delay and thereby also an adaptation to changes during a detection of the magnetic resonance signals.

In one form of embodiment of the magnetic resonance apparatus, the magnetic resonance apparatus is configured to send out a synchronization signal with a time stamp. What has been stated previously applies in relation to the time stamp, (e.g., the time stamp may be modulated as digital or analog). Since the signal is not used for image acquisition and also does not have to be sent out at the same time as the image acquisition, there is no need to take care that the image acquisition is not being disrupted. Forms of embodiment in which the signal is sent out in parallel during the image acquisition are provided. Then, for example, the spread spectrum technique or the use of frequencies as well as the magnetic resonance signals, where these frequencies still lie in the receive range of the local coils, may be used. The local coil is then configured for and is capable of receiving the synchronization signal and of forwarding the synchronization signal to a receiver of the magnetic resonance apparatus, so that the apparatus may evaluate the time stamp.

In this way, the magnetic resonance tomograph is able, in an advantageous way, to carry out the calibration measurement for the variable delay with few additional means.

In one conceivable form of embodiment of the magnetic resonance apparatus, the signal processing process that is carried out depending on the variable delay is a time-dependent mid-frequency correction. Mid-frequency corrections are an option for compensating for temporal fluctuations of the B0 field. Such fluctuations may occur, for example, when eddy currents are generated by gradients in shielding of the patient tunnel, which then decay exponentially with half-lives in ms periods (e.g., greater than 0.1 ms, 1 ms, 5 ms, 10 ms or 50 ms). The reference point in this case is the points in time of the gradients, which are known to a controller of the magnetic resonance apparatus. By the mid frequency of the received magnetic resonance signal being tracked by the time-dependent B0 field and thus by the variable Larmor frequency, the effect may be compensated for the subsequent signal processing steps. This may be undertaken, for example, by the magnetic resonance signal being mixed with a variable oscillator frequency, which is tracked by the temporal course of the B0 magnetic field fluctuation. In this case, the variable signal delay between the receipt of the magnetic resonance signal in the local coil and the entry of the magnetic resonance signal at the receiver of the magnetic resonance signal is then to be known and taken into account.

This may be achieved, however, by the mid-frequency correction already taking place in the local coil, where the timing is undertaken depending on the local clock. The local clock is synchronized with the central clock and in this way, for example, provides the correct time reference to the gradients. In one embodiment, the magnetic resonance signal may be furnished with a time stamp of the local clock, and a mid-frequency correction may only be undertaken in a receiver of the magnetic resonance apparatus with the aid of this time stamp, since the time stamp of the local clock, due to the synchronization with the central clock, also establishes the time reference to the central clock and the gradient signals.

In one embodiment, through the variable tracking of the mid frequency of the magnetic resonance signal, dynamic changes of the B0 magnetic field may be compensated for transparently for the subsequent signal processing steps.

In one possible form of embodiment of the magnetic resonance apparatus, the magnetic resonance apparatus is configured to detect the transmitted magnetic resonance signal in a time window depending on the delay determined. In this case, a period of time in which a receiver of the magnetic resonance apparatus detects the incoming magnetic resonance signal for the signal processing (e.g., digitizes the magnetic resonance signal and/or stores or forwards the magnetic resonance signal) is referred to as the time window. Magnetic resonance signals that also have information about imaging may only be detected within a sequence in specific periods of time, which, for example, have a temporal reference to the excitation pulse and/or to gradients. These periods of time are to be hit as precisely as possible in order to acquire the data efficiently, avoid superfluous data without information about imaging, and obtain an image quality that is as good as possible. In such cases, discrepancies within the framework of the variable delay are also relevant and may also be compensated for by knowing about the discrepancies (e.g., by the data acquisition or processing being delayed accordingly in a receiver).

This may also be achieved by the local coil only detecting or forwarding magnetic resonance signals in the time window, where the beginning of the time window and the end of the time window are predetermined by the local clock, which, on account of the synchronization, establishes the correct relationship to the central clock and to the temporal courses of the image acquisition or sequence. In one embodiment, the local coil may detect the magnetic resonance signals, provide the magnetic resonance signals with a time stamp of the local clock, and the receiver may detect the magnetic resonance signals within the time window with the aid of the time stamp.

By a time window that is dependent on the variable delay, the image quality may be improved and/or the signal processing made more efficient.

In one conceivable form of embodiment of the magnetic resonance apparatus, the magnetic resonance apparatus has a buffer. The buffer may be provided, for example, in a receiver of the magnetic resonance apparatus in order to store the digitized magnetic resonance signal. If, for example, different delays occur for different channels of a local coil and the signals are to be combined or related to one another for processing, the buffer allows these different delays to be compensated for and the channels to be synchronized.

In one conceivable form of embodiment of the method, the test signal is a magnetic resonance signal of a sample. In another form of embodiment, a calibration signal may be sent out instead of the excitation pulse with a transmitter of the magnetic resonance tomograph, and may be detected directly with the local coil and for the variable delay to be determined. For this, the local coil and the subsequent signal processing may, however, evaluate the signal in the receiver. On account of the great power of the excitation pulses, the local coil is to have a correspondingly high dynamic for this or have corresponding attenuation. As an alternative or in addition, the transmitter may also be configured to generate quite weak calibration signals that do not overload the receive path. In accordance with the present embodiments, there may also be provision, however, that, within the framework of the calibration measurement, it is not the transmitted signal itself that is evaluated but a magnetic resonance signal caused by the transmitted signal in a sample. In one embodiment, in this case, the sample is a phantom with predetermined properties (e.g., relating to a delay of the magnetic resonance signal). In one embodiment, the magnetic resonance signal has temporally defined changes impressed upon the magnetic resonance signal by interventions of the magnetic resonance tomograph (e.g., by predetermined changes to the gradient field or fields).

A calibration measurement may also be carried out in this way without modified hardware in the transmit and/or receive path.

In one form of embodiment of the method, the magnetic resonance apparatus, in the synchronization act, sends a synchronization message to the local coil. The synchronization message contains the information required for a synchronization of the central clock and the local clock.

The information is, for example, information about the current time of the central clock. This is not restricted to a time specification in the classical sense of date, hour, minutes, or the like, but may be any other automatically exploitable time specification. Conceivable, for example, is a counter state with a predetermined zero point.

There is information about a delay of the message in the magnetic resonance apparatus. This may be composed, for example, of the times that are needed for the central clock to be read out by a controller, for the message to be composed with the controller, and to send the message out to the local coil. These times may be essentially predetermined and may be held in a memory of the controller. Times for a transmission of the information may also be taken into account, although this is negligible for wireless transmission and a distance in a magnetic resonance apparatus.

In this way, account is also taken of the message being processed, and the synchronization of the clocks is improved.

In one conceivable form of embodiment of the method, the local coil has information about a message delay in the local coil. A message coming in from the magnetic resonance apparatus is transmitted from the interface to a controller of the local coil and written into the local clock there. The time needed for this may, for example, be held in a memory of the local coil. The value to which the local clock is to be set during synchronization is then essentially given by the current time of the central clock contained in the message, plus the message delay in the magnetic resonance apparatus in the message transmitted, plus the message delay in the local coil.

The storage of the message delay in the coil enables the synchronization process to be arranged from the viewpoint of the controller of the magnetic resonance apparatus independently of the local coil and thus the software variants to be reduced.

In one embodiment, the message delay may be determined by a loop, by the magnetic resonance apparatus sending a message to the local coil, and by the coil responding. The message delay in one direction may then be assumed, assuming a symmetrical connection, to be approximately half the so-called round-trip delay, and transferred as information relating to the message delay. Conversely, the local coil may also determine the delay in the same way, and the delay may be added to the time of the central clock transferred in the message.

In one embodiment, the information about the message delay may be transferred in the message by the value already being added to the transmitted time of the central clock.

The characteristics, features, and advantages of this present embodiments described above, as well as the manner in which these are achieved, will become clearer and easier to understand in conjunction with the description of the exemplary embodiments given below, which will be explained in greater detail in conjunction with the drawings.

### BRIEF DESCRIPTION OF THE DRAWINGS

FIG. 1 shows a schematic diagram of an example embodiment of a magnetic resonance tomograph;

FIG. 2 shows a schematic diagram of details of an example embodiment of a magnetic resonance tomograph;

FIG. 3 shows an example a schematic flow diagram of an embodiment of a method; and

FIG. 4 shows an example of a schematic flow diagram of an embodiment of a method.

### DETAILED DESCRIPTION

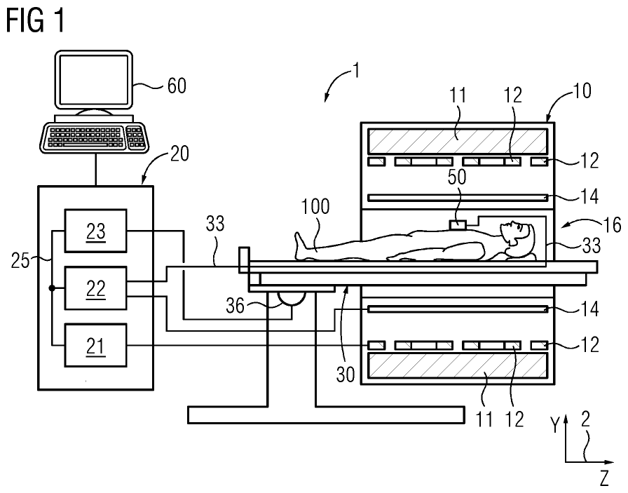

FIG. 1 shows a schematic diagram of a form of embodiment of a magnetic resonance apparatus using a magnetic resonance tomograph 1 as an example. The remarks about synchronization and about time reference of a magnetic resonance measurement apply, however, not only to imaging measurements of a magnetic resonance tomograph 1, but, for example, also to spectral or to other magnetic resonance measurements by a magnetic resonance apparatus that do not lead to any imaging.

The magnet unit 10 of the magnetic resonance tomograph 1 has a field magnet 11 that generates a static magnetic field B0 for alignment of nuclear spins of samples or of the patient 100 in an imaging region. The imaging region is characterized by an extremely homogeneous static magnetic field B0, where the homogeneity relates, for example, to the magnetic field strength or amount. The imaging region is almost spherical in shape and is arranged in a patient tunnel 16 that extends in a longitudinal direction 2 through the magnet unit 10. A patient couch 30 is able to be moved in the patient tunnel 16 by the drive unit 36. Usually, the field magnet 11 involves a superconducting magnet that may provide magnetic fields with a magnetic flux density of up to 3T, with the most recent devices of even more than this. For lower magnetic field strengths, however, permanent magnets or electromagnets with normally conducting coils may also be used.

Further, the magnet unit 10 has gradient coils 12 that are configured, for spatial differentiation of the detected imaging areas in the examination volume, to superimpose on the magnetic field B0 temporally and spatially variable magnetic fields in three spatial directions. The gradient coils 12 may be coils of normally conducting wires that may generate fields orthogonal to one another in the examination volume.

The magnet unit 10 likewise has a body coil 14 that is configured to radiate a radio-frequency signal supplied via a signal line into the examination volume and to receive resonance signals emitted from the patient 100 and output the resonance signals via a signal line.

A control unit 20 supplies the magnet unit 10 with the various signals for the gradient coils 12 and the body coil 14 and evaluates the received signals.

Thus, the control unit 20 includes a gradient controller 21 that is configured to supply the gradient coils 12 via supply lines with variable currents that, with time coordination, provide the desired gradient fields in the examination volume.

Further, the control unit 20 has a radio frequency unit 22 that is configured to generate a radio-frequency pulse with a predetermined temporal course, amplitude, and spectral power distribution for excitation of a magnetic resonance of the nuclear spins in the patient 100. In this case, pulse powers in the range of Kilowatts may be reached. The excitation signals may be radiated out via the body coil 14 or also via a local transmit antenna into the patient 100.

A device controller 23 communicates via a signal bus 25 with the gradient controller 21 and the radio frequency unit 22.

For receipt of the magnetic resonance signal, a local coil 50 of the present embodiments is arranged on the patient 100 in the patient tunnel 16 in order to detect magnetic resonance signals from an examination region in the immediate vicinity with the greatest possible signal-to-noise ratio. The local coil 50 is connected for signaling via a connecting line 33 to a receiver in the radio frequency unit 22. The signal connection may also be wireless, however.

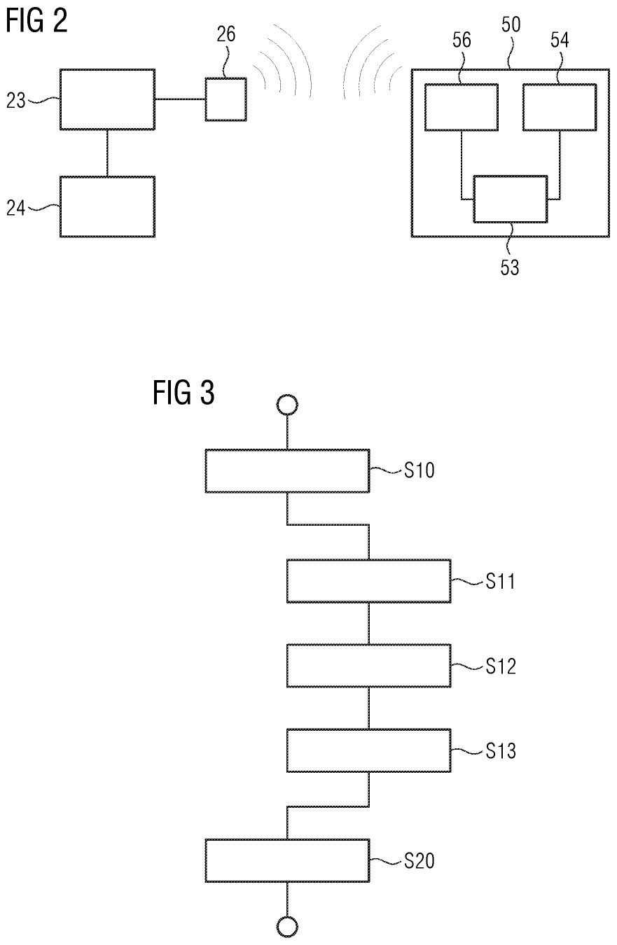

FIG. 2 shows a schematic diagram of details of an example of a magnetic resonance tomograph 1.

The control unit 20 of the magnetic resonance tomograph 1 has a central clock 24 or clock generator. In one embodiment, all clock pulses and time sequences of the magnetic resonance tomograph 1 during an image acquisition are derived from the central clock. For example, the central clock 24 may supply the radio frequency unit 22 and the gradient controller 21 with clock pulses and absolute time specifications. Absolute time specifications are understood in this case, unlike clock pulses that in each case only specify periods of constant length, as time specifications that specify a distance in time from a common predetermined reference point in time. This may, for example, be a counter state for a counter that counts pulses of the central clock generator, or another time specification, such as, for example, consisting of date, hours, minutes, seconds, and fractions thereof.

Further, the control unit 20 in FIG. 2 has a wireless transmission facility 26, via which the controller 23 of the control unit 20 sends data to the local coil 50 and/or receives data from the local coil. The wireless transmission facility may use standards such as WIFI or Bluetooth, for example, but proprietary transmission protocols may also be provided. The wireless transmission may also be optical, where optical may also include non-visible wavelengths of the light such as near-infrared. A wired transmission unit is also possible, however.

The local coil 50 has a complementary wireless transmission facility 56 that is configured to receive data from the control unit 20 via the wireless transmission unit 26 of the control unit 20, and/or to send the data to the wireless transmission unit 26 of the control unit 20. What has been stated previously about the wireless transmission unit 26 applies here too. In one form of embodiment, the local coil 50, like the control unit 20, may use a wired transmission unit.

A transmission of signals between the control unit 20 and the local coil 50 is associated with a delay in such cases. With clock/time signals, for example, this may be a readout delay when reading out the central clock, a delay of the controller 23 when forming a message for transmission, and/or finally a delay in the wireless transmission facility 26. In the same way a delay may arise in the local coil 50 (e.g., in the wireless transmission facility 56 or its buffer during receipt, in the transmission between the wireless transmission facility 56 and the local coil controller 53, and/or the local clock 54).

In one embodiment, the local coil 50 may not have a local clock 54, but a transmitted clock or time specification may be used directly in the local coil 50 or in its local coil controller 53.

In the same way, a delay is present for a signal that is transmitted from the local coil 50 to the magnetic resonance tomograph 1.

The delay may change in operation of the magnetic resonance tomograph (e.g., when the local coil 50 is replaced). Also, with different transmission techniques such as WIFI, which are also used by other services, with the frequencies as a jointly used medium, the delays are variable to a certain extent.

FIG. 3 shows a schematic flow diagram of one embodiment of a method.

In act S10, a delay of the magnetic resonance signal between local coil 50 and magnetic resonance tomograph 1 is established.

This may be undertaken, for example, by a calibration measurement. To do this, in act S11, a test signal with a predetermined, known delay is generated by the magnetic resonance tomograph (1). In one embodiment, the magnetic resonance tomograph may generate a radio frequency signal with the radio frequency unit 22. The radio frequency signal may be in a frequency range of the magnetic resonance signals, so that the radio frequency signal may be detected by the receive path for magnetic resonance signals. In one embodiment, the radio frequency signal is also attenuated so that the radio frequency signal does not overload the receive path, and the signal may be evaluated by the receive path. In one embodiment, however, the receive path has an attenuation able to be switched on during the calibration measurement and sufficiently strong so that an excitation pulse does not overload the receive path.

The radio frequency signal is sent out at a predetermined point in time from the controller 23 via an antenna (e.g., the body coil 14).

In one embodiment, the test signal may be provided by a magnetic resonance signal. The test signal in this case is thus not directly an excitation pulse sent out via an antenna (e.g., the body coil 14), but is a magnetic resonance signal brought about by the excitation pulse in a sample. In this case, it is necessary for the magnetic resonance signal to have, at a well-defined point in time, a signal property that is characteristic and is able to be detected with the magnetic resonance tomograph 1 via the local coil 50. In one embodiment, the sample is therefore a phantom with predetermined properties.

In one embodiment, for example, an echo signal (e.g., a spin echo or a gradient echo) may be generated by the magnetic resonance tomograph 1 at a predetermined point in time.

Also possible is the generation of a Free Induction Decay (FID) in the sample as a time mark.

It is also possible for time encoding of the magnetic resonance signal to modulate the signal by a temporally variable gradient field in a temporally predetermined pattern.

In act S12, the test signal is detected by the receive path for magnetic resonance signals (e.g., with the local coil 50 and the magnetic resonance tomograph 1 or a receiver of the magnetic resonance tomograph). Depending on the test signal used, it may be sufficient in this case to detect the point in time at which the received test signal exceeds or falls below a predetermined threshold value, or also to detect the test signal with a temporal course for a further analysis.

In a further act S13, a variable delay is established from the test signal.

When the test signal generated directly via the antenna is used, the time for a propagation of the fields is to be ignored, so that the difference in time between the point in time of the sending out of the test signal via the antenna and the point in time of the arrival of the signal (e.g., exceeding a threshold value of a signal level) at the input of the receiver produces the variable delay directly.

In the modulation of the magnetic resonance signal, the delay is produced by the difference in time between the modulation and the arrival of the modulated signal at the receiver.

With the other test signals, which are generated, for example, by echoes of the spin signals, and an inherent delay between the causally generating signal and the occurrence of the change of the magnetic resonance signal, it is necessary above and beyond this to establish this inherent delay. This may be undertaken, for example, by a Bloch simulation of the reaction of the nuclear spins to the external gradient and B1 fields, either in advance during the definition of the test signal, or later in the controller 23 of the magnetic resonance tomograph 1 during execution. Variable values such as state of the hardware or environmental parameters such as the temperature may then also be included. The variable delay is then produced by the difference in time between the generation of the causal signals such as B1 field or gradient field and the arrival of the characteristic magnetic resonance signal instigated thereby at the receiver minus the inherent delay. It may then also be advantageous, on account the timing of the magnetic resonance signals, to simulate their course with a time parameter, to take this into account in the determination of the inherent delay, and subsequently to determine the inherent delay by an analysis of the magnetic resonance signal arriving at the receiver. In one embodiment, the determination of the parameters may be through a fitting, where the time parameter may be varied and the deviation of the parametrizable model from the detected magnetic resonance signal is minimized.

In one embodiment, the variable delay may be established by a permanent time stamp that is impressed on the received magnetic resonance signal or is added to the received magnetic resonance signal. In one embodiment, an auxiliary signal may be emitted by the magnetic resonance tomograph 1 in the patient tunnel 16 or its vicinity, and the auxiliary signal has time information from a central clock 24 of the magnetic resonance tomograph 1. The auxiliary signal may be configured so that the auxiliary signal may be detected from the receive path of the magnetic resonance tomograph 1 (e.g., by the local coil 50 and a receiver of the radio frequency unit 22 simultaneously with the magnetic resonance signals). This may be achieved, for example, by the auxiliary signal having a frequency close to the frequency range of the magnetic resonance signals, so that the auxiliary signal does not overlap in the frequency spectrum with the magnetic resonance signal, but still lies in a frequency band that the receiver for the magnetic resonance signals detects. In this case, an amplitude of the auxiliary signal is so small that the auxiliary signal does not overload the receiver.

Another possibility is an auxiliary signal that lies in the frequency range of the magnetic resonance signal, but of which the level lies below the noise level of the receiver and that carries the time information with a wideband modulation, so that by a corresponding demodulation method (e.g., with autocorrelation comparable to GPS), the time information may be retrieved in the receiver.

In both cases, the magnetic resonance tomograph 1 may establish the variable delay of the receive path (e.g., in local coil 50 and receiver) by the comparison of the time specification of the central clock 24 with the signal received via the auxiliary signal. In one embodiment, this may be undertaken permanently and also during an image acquisition, so that even short-duration changes may be detected and taken into account.

In act S20, a signal processing process of the magnetic resonance signal is carried out depending on the message delay established.

This may, for example, be an image reconstruction. For image reconstruction, both the phase of the signal and also the amplitude is evaluated as a function of the time (e.g., in relation to the individual events of the sequence such as excitation pulse and gradient signals).

For example, magnetic resonance signals only occur in short time segments of a sequence that also contribute to the contents of an image reconstruction. In order to save on resources, it is therefore possible only to detect this data in these periods of time and to digitize the data, for example, by an A/D converter in a receiver and store the data or further process the data immediately. In this case, these periods of time are defined relative to the initiating signals such as excitation pulses and gradients. The variable delay leads to deviations from these ideal points in time during the detection of the signals. Thus, the detection period may be shifted, for example, by the variable delay established. In one embodiment, the data in intermediate storage may be buffered, and only the time window shifted by the variable delay may be evaluated. In other words, the buffer enables a predetermined constant signal delay to be made from the variable delay for the subsequent signal processing processes, which may be taken into account by a simple constant offset. If relative time references between individual channels are relevant, the variable delay between the individual channels may be brought to zero by the buffer.

There are further noise effects that have a fixed time reference as regards the sequence. One example thereof are eddy currents that are created by gradient signals and their magnetic fields in metallic elements of the patient tunnel 16. For a correction of these noise effects, this is to be carried out with a time reference to the sequence and thus as a function of the variables delay established on the received magnetic resonance signals. Eddy currents lead, for example, to a time-dependent change of the static magnetic field B0 and thus to a shifting of the mid frequency of the received magnetic resonance signal. This may be rectified by a time-dependent correction of the mid frequency, so that the subsequent steps of image reconstruction may start from an undisturbed constant mid frequency. This may be realized technically by the magnetic resonance signals being mixed down with a temporally variable frequency, such as may be created by a digital oscillator (Numerically Controlled Oscillator (NCO)). Its input signal for frequency control is likewise to be shifted by the variable delay.

The delay is also able to be compensated for when the local clock 54 is synchronized with the central clock 24, and actions of the local coil 50 in relation to the image detection are carried out with the time reference on the synchronized local clock 54 and thus also time reference to the central clock 24.

It is explained below, for the method of the present embodiments, how the clocks are synchronized and how the image acquisition may be carried out with the help of the synchronized local clock 54.

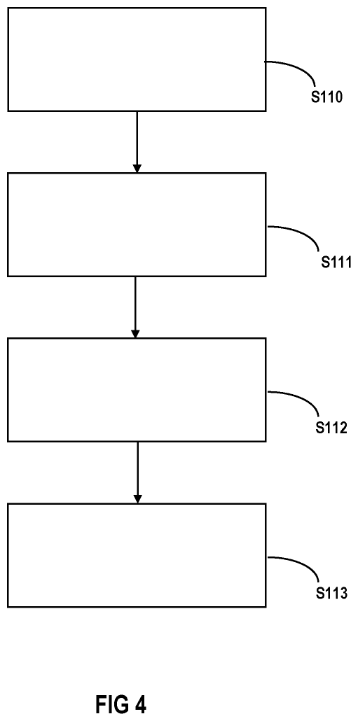

FIG. 4 shows a schematic flow diagram of a further form of embodiment of the method of the present embodiments.

In act S110, the local clock 54 and the central clock 24 are synchronized.

One possibility for synchronization is a synchronization message that is created by the control unit 20 in act S111. The synchronization message contains the information necessary for a synchronization of central clock 24 and local clock 54.

The synchronization message is to have a time specification of the central clock 24. This may be a counter state with a defined zero point as reference point in order to make possible an absolute time specification. In one embodiment, a time specification with a known time system such as date and time of day, with a temporal resolution, however, as is necessary for magnetic resonance tomography, is provided. For the execution steps of the sequence such as detuning, time windows for the data acquisition, and compensation for noise effects such as eddy currents, a temporal resolution of less than 10 ms, 5 ms, 1 ms, or 100 microseconds may be required. For the evaluation of the magnetic resonance signals for image reconstruction (e.g., of the phase), a resolution of less than 1 microsecond, 100 ns, or 10 ns may be required. It may, however, be sufficient here for the phase relationship to only be defined relatively (e.g., between the signals of different channels or antenna coils of the local coil 50).

For the required resolution, a message delay is also relevant, which arises from the reading out of the central clock 24 by the control unit 20, preparation, and/or transmission of the synchronization message. Delays may also arise on the local coil 50 side through the receipts and the preparation by the local coil controller 53 delays. In one embodiment, the delays in the magnetic resonance tomograph 1, during the transmission and in the local coil 50, and thus the message delay, are essentially constant in this case, thus varying by less than 10%, 5%, or 1%.

In one embodiment, a synchronization message may directly have information about the message delay (e.g., at least about the delay that arises up to the local coil 50). The local coil controller 53 may then establish the time for the local clock 54 from the established time of the central clock 24, plus the message delay from the synchronization message, plus a predetermined delay in the local coil 50, and set or synchronize the local clock 54 accordingly. The delay in the local coil 50 may be stored, for example, in the local coil controller 53.

The message delay may, however, also be taken into account indirectly in the synchronization message, by the message delay already being added to the time of the central clock 24 before the synchronization message is sent. In one embodiment, the delay may be stored by the local coil 50 in the magnetic resonance tomograph 1 and may be taken into account already in the message delay of the synchronization message.

In act S112, the synchronization message is sent via the wireless transmission facilities 26, 56 to the local coil controller 53. The message may be sent by a standardized wireless transmission protocol such as WIFI or Bluetooth. Other proprietary wireless and, for example, optical transmission methods may also be provided, however.

In act S113, the local clock of the local coil 50 is finally set by the local coil controller 53 depending on the synchronization message. This step differs depending on the contents of the synchronization message.

If the delays in the magnetic resonance tomograph 1 and the local coil 50 are already taken into account, as previously described, in the transferred time of the central clock 24, then the local coil controller 53 writes the transferred time into the local clock 54.

A value for a delay of the synchronization between receipt by the local coil 50 and the setting of the local clock 54 may also be stored in the local coil controller 53. The local coil controller 53 adds the transferred message delay and/or stored delay to the transferred time of the central clock 24 and writes the result into the local clock 54.

In one form of embodiment of the method, it the message delay from the magnetic resonance tomograph 1 may be established by a message loop, by the magnetic resonance tomograph 1 sending a synchronization message to the local coil 50, and by the coil responding with a message. The message delay in one direction may then be assumed to be approximately half the round-trip delay, when the message transfer between local coil 50 and magnetic resonance tomograph 1 is essentially temporally symmetrical and may be transferred as information about the message delay in the synchronization message. Conversely, the local coil controller 23 may establish the message delay in the same way by a mirrored message to the magnetic resonance tomograph 1, and the message delay from the local coil controller 23 may be added to the time of the central clock 24 transferred in the synchronization message.

In act S20, a signal processing process of the magnetic resonance signal is further carried out, depending on the message delay established.

This may, for example, be an image reconstruction. For image reconstruction, both the phase of the magnetic resonance signal and also the amplitude are evaluated as a function of the time (e.g., as regards the individual events of the sequence such as excitation pulse and gradient signals). The temporal reference to the excitation pulse is, however, also relevant, for example, for spectral magnetic resonance measurements. For example, magnetic resonance signals only occur in short time segments of a sequence, the contents of which also contribute to an image reconstruction. In order to save resources, it is therefore sensible only to acquire the data in these periods of time and to digitize the data, for example, by an AD converter in a receiver and to store the data or forward the data directly. In this case, these periods of time are defined in relation to the signals to be triggered such as excitation pulses and gradients.

The message delay would lead to deviations from these ideal points in time during the detection of the signals if the local coil 50 or the receiver of the magnetic resonance tomograph 1 were to carry out the image acquisition or the image reconstruction with the aid of a message transmitted from the magnetic resonance tomograph 1 to the local coil 50.

In order to solve this problem, the actions of image acquisition or image reconstruction are carried out in accordance with the present embodiments with reference to the synchronized local clock 54.

Thus, the acquisition period may, for example, be defined in relation to the synchronized local clock 54. For example, the control unit 20 may send, in advance (e.g., with a temporal space before the intended execution), an instruction to the local coil controller 53 to detect the magnetic resonance signals in the period of time between a start time and end time. The start time and the end time are defined in relation to the central clock 24 and thus also to the synchronized local clock 54. In the execution, controlled by the local coil controller 23 with the aid of the local clock 54, the execution is thus also undertaken synchronously to the activities of the magnetic resonance tomograph 1 in relation to the central clock 24.

The possibility also exists of furnishing the detected magnetic resonance signals with a time stamp of the local clock 54. Due to the synchronicity of the local clock 54 and the central clock 24, the data thus has a fixed time reference to the sequence, which is likewise controlled by the central clock 24. This time reference may subsequently be used in a signal processing in a receiver of the magnetic resonance tomograph 1 or in an image reconstruction.

There are noise effects, for example, that have a fixed time reference with regard to the sequence. An example of the effects is eddy currents, which are created by gradient signals and their magnetic fields in metallic elements of the patient tunnel 16. For a correction of these noise effects, it is then likewise necessary to carry this out on the received magnetic resonance signals with a time reference to the sequence and thus as a function of the variable delay. Eddy currents lead, for example, to a time-dependent change of the static magnetic field B0 and thus to a shifting of the mid frequency of the received magnetic resonance signal. This may be rectified by a time-dependent correction of the mid frequency, so that the subsequent steps of image reconstruction may start from an undisturbed constant mid frequency.

Technically, this may be realized by the magnetic resonance signals being mixed down with a temporally variable frequency, such as may be created, for example, by a digital oscillator (e.g., Numerically Controlled Oscillator (NCO)). If the mixing down already takes place in the local coil 50, then the NCO, as already explained for detection, may be controlled with the aid of the control unit 20 of the local coil controller with the help of the local clock 54 synchronously to the central clock 24.

In one embodiment, a receiver of the magnetic resonance tomograph 1 may carry out the function of the NCO, where the NCO is controlled with the aid of the time stamp of the magnetic resonance data. Via the synchronicity of local clock 54, which creates the time stamp, and the central clock 24, in this way, the frequency correction may be carried out by the NCO synchronous to the central clock 24 and the sequence.

Although the invention has been illustrated and described in greater detail by the example embodiments, the invention is not restricted by the disclosed examples, and other variations may be derived herefrom by the person skilled in the art without departing from the scope of protection of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance apparatus comprising:
a controller; and
a local coil configured for acceptance and transmission of magnetic resonance signals to the controller,
wherein a delay of a magnetic resonance signal of the magnetic resonance signals between receipt by the local coil and arrival at the controller is variable, the controller being configured to establish the delay,
wherein the controller is further configured to carry out a signal processing process of the transmitted magnetic resonance signal depending on the delay established.

2. The magnetic resonance apparatus of claim 1, wherein the controller is further configured to establish the delay using a calibration measurement.

3. The magnetic resonance apparatus of claim 1, wherein the local coil comprises an encoder configured to impress a time stamp into the magnetic resonance signal, and the controller comprises a decoder configured to decode the time stamp.

4. The magnetic resonance apparatus of claim 1, wherein the controller is further configured to:
send out a synchronization signal with a time stamp; and
receive the synchronization signal via the local coil and evaluate the time stamp.

5. The magnetic resonance apparatus of claim 1, wherein the signal processing process is a time-dependent mid-frequency correction.

6. The magnetic resonance apparatus of claim 1, wherein the controller is configured to detect the transmitted magnetic resonance signal in a time window depending on the delay established.

7. The magnetic resonance apparatus of claim 1, wherein the controller comprises a buffer configured to compensate for the delay.

8. A magnetic resonance apparatus comprising:
a controller;
a local coil configured for acceptance and transmission of magnetic resonance signals to the controller; and
a central clock,
wherein a delay of a magnetic resonance signal of the magnetic resonance signals between the controller and the local coil is variable,
wherein the local coil comprises a local clock, and the controller is configured to synchronize the local clock with the central clock,
wherein the controller is further configured to carry out a magnetic resonance measurement depending on the local clock.

9. The magnetic resonance apparatus of claim 8, wherein the local coil is configured to undertake a mid-frequency correction of a received magnetic resonance signal depending on the local clock.

10. The magnetic resonance apparatus of claim 8, wherein the local coil is configured to detect the magnetic resonance signal in a time window depending on the local clock.

11. The magnetic resonance apparatus of claim 8, wherein the controller comprises a buffer for the magnetic resonance signal.

12. The magnetic resonance apparatus of claim 8, wherein the local coil comprises an encoder for a time stamp in a received magnetic resonance signal, and the controller comprises a decoder configured for decoding the time stamp.

13. A method for operating a magnetic resonance apparatus, wherein the magnetic resonance apparatus comprises a controller and a local coil, the local coil being configured for acceptance and transmission of magnetic resonance signals to the controller, wherein a delay of a magnetic resonance signal of the magnetic resonance signals between receipt by the local coil and arrival at the controller is variable, the method comprising:
establishing the delay of the magnetic resonance signal between the local coil and the controller; and
carrying out a signal processing process of the transmitted magnetic resonance signal depending on the delay established.

14. The method of claim 13, wherein establishing the delay comprises a calibration measurement, wherein the calibration measurement comprise:
creating a test signal with a predetermined delay by the magnetic resonance apparatus;
detecting the test signal with the local coil and the controller;
determining the variable delay from a time difference between the creating of the test signal and the detecting of the test signal by the controller.

15. The method of claim 14, wherein the test signal is a magnetic resonance signal of a sample.

16. A method for operation of a magnetic resonance apparatus, wherein the magnetic resonance apparatus comprises a controller and a local coil configured for acceptance and transmission of magnetic resonance signals to the controller, the magnetic resonance apparatus further comprising a central clock and the local coil comprising a local clock, wherein a delay of a signal between the controller and the local coil is variable, the method comprising:
synchronizing the local clock with the central clock; and
carrying out an image acquisition step depending on the local clock.

17. The method of claim 16, wherein the synchronizing comprises sending a synchronization message to the local coil,
wherein the synchronization message includes information about a current time of the central clock and about a message delay in the controller.

18. The method of claim 17, wherein the local coil includes information about a message delay in the local coil, and
wherein the synchronizing comprises setting the local clock to a value equal to the current time of the central clock in the synchronization message plus the message delay in the controller plus the message delay in the local coil.
